(19) United States
(12) Patent Application Publication
(10) Pub. No.: US 2024/0195364 A1
(43) Pub. Date: Jun. 13, 2024

(54) TRANSCONDUCTOR WITH CURRENT LIMITER

(71) Applicant: Nokia Solutions and Networks Oy, Espoo (FI)

(72) Inventors: Mark Ferriss, Tarrytown, NY (US); Lorenzo Iotti, Brooklyn, NY (US); Alexander Rylyakov, Staten Island, NY (US)

(21) Appl. No.: 18/356,576

(22) Filed: Jul. 21, 2023

Related U.S. Application Data
(60) Provisional application No. 63/431,927, filed on Dec. 12, 2022.

(51) Int. Cl. H03F 1/52; H03F 3/45

(52) U.S. Cl. CPC H03F 1/52; H03F 3/45475; H03F 2200/426

(57) ABSTRACT

An apparatus, such as a coherent optical receiver, includes a transimpedance amplifier (TIA) with differential outputs, and a multi-tanh type current limiter connected across the differential outputs of the transimpedance amplifier. The multi-tanh type current limiter includes two tanh-type current limiters shifted in voltage and connected to subtract an output current thereof from an output current of the TIA.

### CROSS-REFERENCE TO RELATED APPLICATIONS

This application claims the benefit of U.S. Provisional Patent Application No. 63/431,927, filed on Dec. 12, 2022, which is incorporated herein by reference in its entirety.

### FIELD OF INVENTION

Various example embodiments relate to circuits for trans-impedance amplifiers and coherent optical receivers with trans-impedance amplifiers.

### BACKGROUND

Trans-impedance amplifiers (TIAs) are used in high speed fiber optic communication systems to provide a link between optical-to-electrical converters, e.g. photodetectors (PD), and the downstream electronics. A TIA converts the current coming from the PD into a voltage, thus providing transimpedance gain (ZT). This voltage is typically fed to an ADC, and the resulting signal may be processed in the digital domain. The TIA is desirably linear, and has a well-controlled gain in the relevant operating range, so that the ADC receives a voltage that is an about linear representation of the current from the PD, and has a magnitude within the dynamic range of the ADC.

### SUMMARY

The present disclosure provides an apparatus including a limiter of an output current. First embodiments of the apparatus comprise a transimpedance amplifier (TIA) with differential outputs, and a multi-tanh type current limiter connected across the differential outputs of the TIA.

In any of the first embodiments, the multi-tanh type current limiter may comprise first and second tanh-type current limiters connected to subtract an output current thereof from an output current of the TIA. The first and second tanh-type current limiters are biased to be shifted in voltage.

In any of the first embodiments, the first and second tanh-type current limiters may be biased to be shifted by a voltage approximately being a voltage range for linear amplification by the TIA.

In any of the first embodiments, the multi-tanh type current limiter may comprise a multi-tanh doublet. The multi-tanh type current limiter may, in some of such first embodiments, comprise two non-degenerated transistor pairs.

In any of the first embodiments, the TIA may include a degenerated transistor pair at an output thereof. A peak transconductance of each of the first and second tanh-type current limiters may be, in some of such first embodiments, at least double in magnitude a peak transconductance of the degenerated transistor pair.

In any of the first embodiments, the first and second tanh-type current limiters may be biased to have threshold voltages of opposite sign. In some of such first embodiments, the apparatus may further comprise a threshold control circuit for controlling the threshold voltages. In some of such first embodiments, the threshold control circuit may comprise: a first resistor R_{drop} for passing a first current I₁ therethrough, a voltage drop ΔV_{d}=I₁*R_{drop} across the first resistor biasing one of the first and second tanh-type current limiters to have a threshold voltage equal to ΔV_{d}; a transistor for tuning the first current I₁; a voltage feedback circuit comprising a second resistor Rₓ≥10. R_{drop} in parallel with the first resistor; and a reference current source for flowing a reference current I_{ref} through the second resistor Rₓ. The voltage feedback circuit may further comprise an operational amplifier coupled to the transistor for adjusting the first current I₁ to force the voltage drop across the first resistor R_{drop} to be equal to approximately Rₓ. I_{ref}. In some of such first embodiments, the threshold control circuit may comprise: a resistor R_{drop} having first and second terminals connected to positive and negative inputs, respectively, of the first and second tanh-type current limiters; a first current source comprising a transistor and connected to the second terminal of the resistor R_{drop} to flow a first current I₁ therethrough, so that a voltage drop ΔV_{d}=I₁*R_{drop} across the resistor R_{drop} provides one of the threshold voltages for turning on the corresponding one of first and second tanh-type current limiters; a resistor Rₓ having a first terminal connected to the first terminal of R_{drop}, and a second terminal connected to a second current source for generating a reference current I_{ref}, wherein R_{x≥}10·R_{drop}; an operational amplifier having an output connected to a base or gate of the transistor of the first current source, and inputs connected to the second terminals of the resistors Rₓ and R_{drop}, so as to set ΔV_{d} approximately equal in magnitude to I_{ref}*Rₓ.

In any of the first embodiments, the first and second tanh-type current limiters may be biased to have I-V characteristics shifted relative to each other by a voltage offset approximately being a voltage range for linear amplification by the transimpedance amplifier.

In any of the first embodiments, the apparatus may comprise a coherent optical receiver including the TIA.

Second embodiments of the apparatus comprise a limiting amplifier operable to convert a differential input voltage Vᵢₙ to a differential output current. The limiting amplifier comprises a first circuit having a substantially non-zero first trans-conductance T_{c1} for |Vᵢₙ|≤V₁, and a limiter circuit having a second trans-conductance T_{c2}, wherein T_{c2} is smaller in magnitude than T_{c1} for |Vᵢₙ|≤V₂<V₁, and T_{c2} is greater in magnitude than T_{c1} in some range of |Vᵢₙ| above V₂. The limiter circuit is connected so that an output current of the limiter circuit is subtracted from an output current of the first circuit.

In any of the second embodiments, the first circuit may comprise an emitter-degenerated or source-degenerated transistor pair.

In any of the second embodiments, the limiter circuit may comprise two non-degenerated transistor pairs connected to have two DC voltage offsets of opposite sign.

In any of the second embodiments, the limiter circuit may comprise a multi-tanh doublet. In some of such second embodiments, the multi-tanh doublet may comprise two non-degenerated transistor pairs connected to have two DC voltage offsets of opposite sign.

In any of the second embodiments, the apparatus may comprise a coherent optical receiver including the limiting amplifier.

### BRIEF DESCRIPTION OF THE DRAWINGS

Embodiments disclosed herein will be described in greater detail with reference to the accompanying drawings which represent preferred embodiments thereof, in which like elements are indicated with like reference numerals, and wherein:

FIG. 1 is a schematic block diagram of a coherent optical receiver where the TIA(s) of the present disclosure may be used;

FIG. 2 is a schematic block diagram of a TIA circuit that may be used in the coherent optical receiver of FIG. 1;

FIG. 3 shows a circuit diagram of a transconductor for the TIA circuit of FIG. 2 according to an embodiment of the present disclosure;

FIG. 4 is a graph illustrating output current vs input voltage characteristics for the circuit of FIG. 3; and

FIG. 5 is a schematic circuit diagram of an example threshold control circuit for use in an embodiment of the transconductor of FIG. 3.

### DETAILED DESCRIPTION

In the following description, for purposes of explanation and not limitation, specific details are set forth, such as particular circuits, circuit components, techniques, etc. in order to provide a thorough understanding of the present invention. However, it will be apparent to one skilled in the art that the present invention may be practiced in other embodiments that depart from these specific details. In other instances, detailed descriptions of well-known methods, devices, and circuits may be omitted so as not to obscure the description of the present invention. All statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Furthermore, the following abbreviations and acronyms may be used in the present document:
ADC: Analog to Digital Converter
AGC: Automatic Gain Control
ASIC: Application Specific Integrated Circuit
AV: voltage gain
CMOS: Complementary Metal-Oxide-Semiconductor
DSP: Digital Signal Processor
PVT: Process/supply Voltage/Temperature
RF: Feedback Resistor
TIA: TransImpedance Amplifier
VGA: Variable Gain Amplifier
ZT: transimpedance

FIG. 1 illustrates a block diagram of an example coherent optical receiver 100 of some embodiments of the present disclosure. An optical signal 101 received from an optical communication link (not shown) is mixed with local oscillator (LO) light 103 in an optical hybrid 115. Different mixtures of the optical signal 101 and LO light 103 from four output ports of the optical hybrid 115 are transmitted to two photodiode (PD) pairs 120. Each PD pair 120 may be suitably biased. The two PDs of a pair measure mixtures of the received optical signal light 101 with LO light 103 with different relative phase shifts. The signals from the two PDs of a pair are coupled to the differential inputs of a corresponding TIA circuit 130. Differential outputs of the TIAs 130 are provided to respective ADCs 140, which are, in turn, connected to a DSP 150 for signal processing and data de-modulation.

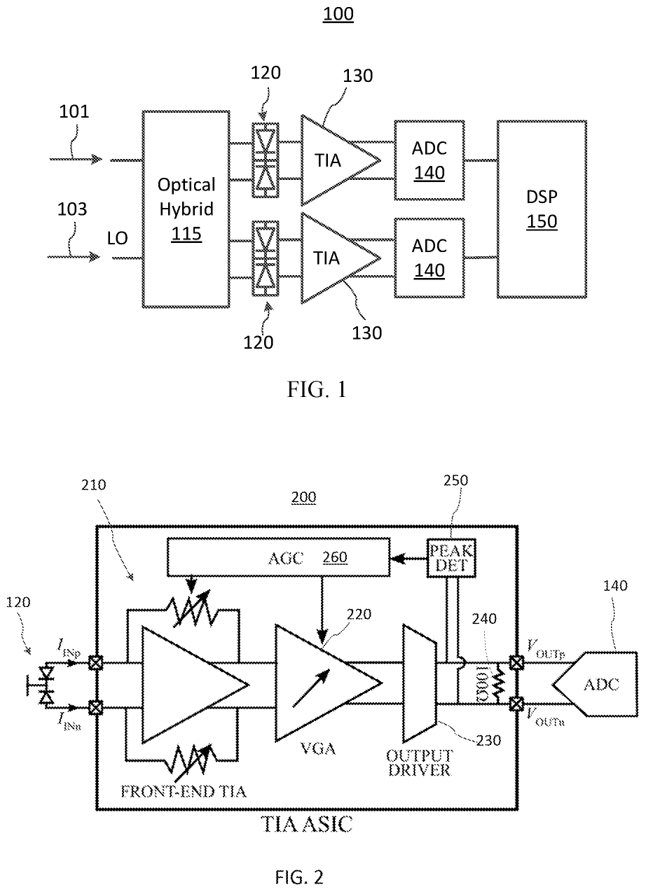

A block diagram of a typical TIA circuit 200 (“TIA 200”), which may be implemented e.g. as an Application-Specific Integrated Circuit (ASIC), is shown in FIG. 2. It includes a front-end TIA (FE-TIA) 210, which converts the PD current(s) I_{INp}, I_{INn} into a voltage signal, followed by a series of one or more Variable Gain Amplifiers (VGA) 220 to provide further voltage amplification, and an output driver 230. The output driver 230 is typically a transconductor, which drives an on-chip termination resistor 240 as well as being connected to the inputs of the ADC 140. The TIA circuit 200 may also include a peak detector 250 to measure the output swing, and an Automatic Gain Control (AGC) loop 260, which adjusts the TIA gain in order to keep the peak output swing at a desired value in the presence of slow variations of the swing of the currents I_{INp}, I_{INn} input to the TIA 200.

For the coherent optical receiver 100 illustrated in FIG. 1, the TIA input signal amplitude can vary suddenly by >10× (20 dB) due to events in the optical network. Such events can substantially change the optical signal propagating to an optical receiver, at a rate much lower than the baud rate or symbol rate of the optical signal 101. In response to such events, gain of the TIA circuit 200 may be adjusted by the AGC 260, so that the amplitude of the output signal remains about constant and remains within a desirable operating range of the ADC 140 connected to receive the output signals V_{OUTp}, V_{OUTn} of the TIA circuit 200.

As the speed of data links increase, the ADC bandwidth also increases. Increasing the ADC bandwidth typically necessitates the use of small feature size transistors, which may be very sensitive to over-voltage stresses, and can be easily damaged if the output voltage of the TIA is too large. Therefore it is of importance that the TIA does not produce output voltage signals of a magnitude that exceed an ADC threshold.

One way to limit swing in a fast and reliable way is to use a diode clamp, commonly used to prevent damage to I/O circuits in case of electrostatic discharge (ESD) events. Below a threshold voltage, the diode acts as a high impedance, and has negligible impact on the signal swing. Above the threshold the diode acts as a low impedance, effectively clamping the maximum swing to the threshold voltage. By properly biasing the diode, the clamping voltage can be set to a desired value.

There are typically two main problems related to implementing a diode clamp in a high-speed linear TIA. The first is that diodes add significant parasitic capacitance, which can significantly worsen the TIA bandwidth and high-frequency output reflection coefficient (S₂₂). Some techniques have been proposed to avoid these drawbacks, but the techniques typically employ resonant circuits that occupy significant area and add design complexity.

Another issue is that approaching the diode threshold voltage, there is a voltage region of ˜200 mV where the diode is not clamping the swing yet, but starts to behave as a nonlinear impedance. Operating the diode in this region has an undesired effect on the TIA harmonic distortion.

On the other hand, operating below but close to the maximum allowed swing is a desired feature in TIAs: this ensures that the ADC full-scale range is fully utilized, which reduces the impact of the ADC quantization noise.

Embodiments of circuits capable of operating linearly up to a certain threshold, and abruptly clamping the voltage above the threshold, may be useful, e.g., in the output driver 230 of the TIA circuit 200 illustrated in FIG. 2.

Some embodiments described herein may utilize a multi-tanh type current limiter. Multi-tanh transconductors employ multiple differential transistor pairs connected in parallel, each biased with a tail current Iⱼ, j=1, 2, . . . being an index of the pair. Each differential transistor pair has a different DC offset Vⱼ, so that the differential transistor pair is balanced (i.e. the “positive” and “negative” currents are about equal) for Vᵢₙ=Vⱼ, where Vᵢₙ is an input voltage. Properly choosing currents Iⱼ and offsets Vⱼ can produce a transconductor with a superior input linear range. Embodiments described herein modify this concept to provide a multi-tanh like current limiter to achieve current clamping, e.g., abrupt current limiting. Herein, a multi-tanh type current limiter refers to a circuit that has differential current output approximately given by a combination of multiple, typically two, rounded step-functions of input voltages (“tanh-like” functions), with transition regions of the rounded step functions being shifted in voltage relative to each other. The voltage shift between the transition regions is selected. e.g. by suitably biasing corresponding sub-circuits with the “tanh-like” I-V characteristics, to limit (“clamp”) the output current when the input voltage shifts outside a voltage range of TIA linear operation.

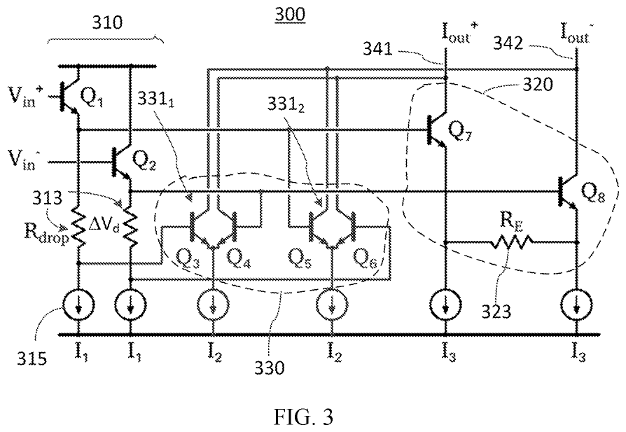

FIG. 3 shows an example circuit embodiment of a current limiting transconductor circuit 300 having differential outputs (“circuit 300”). The circuit of FIG. 3 may be used, e.g. as an output driver of a TIA circuit, such as, the output driver 230 of the TIA 200 illustrated in FIG. 2. An emitter follower 310 (i.e., the circuit including bipolar transistors Q₁ and Q₂) drives a degenerated differential bipolar transistor pair 320 (transistors Q₇ and Q₈ with a degeneration resistor R_{E}, “first circuit”), as well as a limiter circuit 330. The limiter circuit 330 includes two undegenerated differential bipolar transistor pairs 331 (transistors Q₃ and Q₄) and 332 (transistors Q₅ and Q₆), which are connected to the outputs with opposite polarity of bipolar transistors Q₇ and Q₈, and act as limiters. The limiter circuit 330 is connected to subtract the currents it generates from the currents generated by the first circuit 320 in response to the input voltage Vᵢₙ.

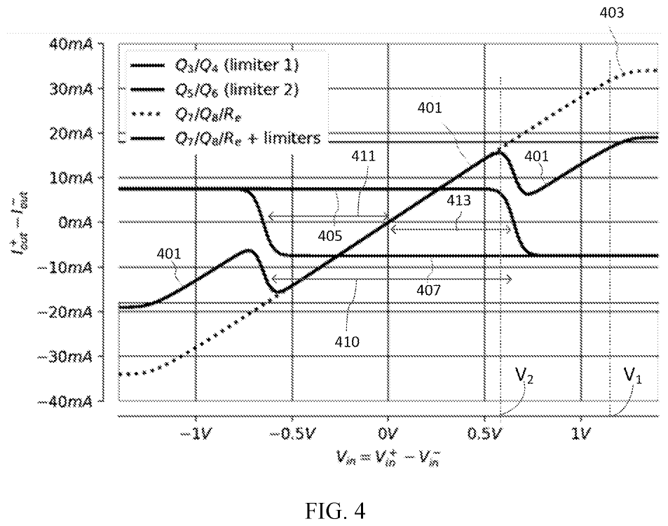

The degenerated differential transistor pair Q₇ and Q₈, i.e. the first circuit 320, may function as a linear transconductor, and the resistor R_{E} 323 is typically set to achieve a desired linear range of input voltages. In an example embodiment, the I-V response of the first circuit 320 to variations of the input voltage Vᵢₙ=(Vᵢₙ₊−Vᵢₙ₋), e.g. as illustrated by the dotted curve 403 in FIG. 4, is approximately linear in a voltage range, e.g. from −V₁ to +V₁, that somewhat exceeds a target operating range of the circuit; in the example of FIG. 4, V₁≅1.1 V.

In an embodiment, the main transductor circuit of FIG. 3 (“first circuit” 320) is an output stage of a TIA circuit, e.g. of the output driver 230 of the TIA 200 illustrated in FIG. 2, and the differential outputs 341, 342 (marked with respective output currents Iₒᵤₜ⁺ and Iₒᵤₜ⁻) of the circuit 300 of FIG. 3 are the differential outputs of the TIA circuit, e.g. TIA 200, so that the limiter circuit 330 of FIG. 3, formed with the undegenerated transistor pairs 331₁ (Q₃/Q₄) and 331₂ (Q₅/Q₆), is connected across the differential outputs 341, 342 of the circuit 300. The two sub-circuits 331₁, 331₂ of the limiter circuit 330, based on the differential transistor pairs Q₃/Q₄ and Q₅/Q₆, respectively, may be separately referred to as limiter transconductors 331, tanh-type current limiters 331, or simply as limiters 331. Together, these two limiter transconductors form a multi-tanh type current limiter, which may also be referred to as a multi-tanh doublet (current) limiter.

The first and second tanh-type current limiters, 331₁ and 331₂, implemented respectively with the transistor pairs Q₃/Q₄ and Q₅/Q₆, are DC-biased to have I-V characteristics, e.g. 405 and 407 in FIG. 4, that are shifted relative to each other by a voltage offset 410, said voltage offset 410 approximately being a voltage range for linear amplification of the transimpedance amplifier. In the illustrated embodiments, the transistor pairs Q₃/Q₄ and Q₅/Q₆ are biased to have input DC voltage offsets 411, 413 of opposite signs (relative to a common-mode DC voltage, if present), V_{offset1} and V_{offset2}. The input DC voltage offsets V_{offset1} and V_{offset2} may also be referred to herein as threshold voltages for the respective tanh-type transconductors. Magnitude of each of these voltage offsets is given by a voltage drop ΔV_{d} across a corresponding resistor 313. In the illustrated embodiment (FIG. 3) the two resistors 313 are of equal resistance value R_{drop}, so that |V_{offset 1}|=|V_{offset 2}|=ΔV_{d}=R_{drop}*I₁, however embodiments with different values of the voltage offsets 411, 413 are also within the scope of this disclosure. Here In is the emitter current of the transistors Q₁ and Q₂.

Due to the DC offsets 411 and 413, for a small input voltage swing the differential transistor pairs Q₃/Q₄ or Q₅/Q₆ are effectively “railed”; at these voltages their transconductance (dI/dV) is close to 0. Here “railed” means that the corresponding transistor pair 331₁ (Q₃/Q₄) or 331₂ (Q₅/Q₆) operates in a saturation regime, where approximately all current I₂ flows through one branch of the corresponding pair 331₁ or 331₂, e.g. the transistor Q₄ or the transistor Q₅ in the circuit 300 of FIG. 3. In a typical embodiment, when the magnitude |Vᵢₙ| of the input differential voltage Vᵢₙ=(Vᵢₙ₊-Vᵢₙ₋) to the circuit 300 is smaller than, e.g., about 0.8 ΔV_{d}, the transconductance of the differential transistor pair 331₁ (Q₃/Q₄) or 331₂ (Q₅/Q₆) is much smaller, e.g. by a factor of 5, or preferably a factor of 10, than a transconductance of the first circuit 320 (the degenerated differential transistor pair Q₇ and Q₈).

When the input signal Vᵢₙ approaches one of threshold voltages V_{offset} ?=+ΔV_{d} or V_{offset1}=−ΔV_{d}, one of the limiter differential transistor pairs, 331₁ (Q₃/Q₄) or 331₂ (Q₅/Q₆), turns on, and subtracts current from the output, thus reducing the overall transconductance of the circuit 300 of FIG. 3. Due to the exponential turn-on behavior of undegenerated bipolar differential pairs, this effect happens rather abruptly, and typically only significantly affects the output differential signal when the magnitude of the input differential signal approaches ΔV_{d}. As a result, the output current is clamped for |Vᵢₙ|>ΔV_{d}, with a low impact on the circuit linearity for Vᵢₙ<ΔV_{d}.

A simulated output differential current swing as a function of input differential voltage Vᵢₙ for the circuit in FIG. 3 is shown in solid black in FIG. 4. The output current (curve 401) linearly tracks the input differential voltage up to a given threshold+\−V₂˜ΔV_{d} (˜0.6V in the illustrated example), and above the threshold (below for negative Vᵢₙ) is clamped to below a given value (20 mA in the illustrated example). The I-V characteristics (output current as a function of input voltage) of the limiters 331₁ (Q₃/Q₄) and 331₂ (Q₅/Q₆) are tanh-type functions having opposite offsets, +\−ΔV_{d} respectively. The transconductance dI/dV of the limiters reaches its peak value in their respective transition regions, where |Vᵢₙ|˜ΔV_{d}, where it is substantially greater, e.g. 2-5 times greater, in magnitude than the trans-conductance of the output stage of the circuit 300 (the first circuit 320, degenerated transistor pair Q₇/Q₈), with the transition being typically abrupt, and does not affect linearity significantly within the nominal linear region between about −V₂ and about +V₂.

Unlike a diode clamp, the clamping technique implemented in the circuit 300 of FIG. 3 does not typically significantly affect the circuit linearity. Also since the limiter transconductors 331₁ (transistor pair Q₃/Q₄) and 331₂ (transistor pair Q₅/Q₆) are effectively railed during nominal operation, the current clamping technique implemented in FIG. 3 only adds a small input and output capacitance overhead.

FIG. 4 also shows the behavior of the three transconductors 320, 331₁, and 331₂, in the circuit. The I-V characteristic of the main degenerated transconductor 320 (Q₇/Q₈/R_{E}), (“first circuit”), shown in dashed black (curve 403), has a wide linear range, i.e. the transconductance of the main transconductor (“first circuit” 320) is approximately constant in the range from about −1.1.V to +1.1 V in this example. The output current saturates with a gentle transition for very large input swings, greater than about 1.2 V in the illustrated example. The limiter transconductors 331₁ (Q₃/Q₄) and 331₂ (Q₅/Q₆), curves 105 and 106 respectively, are effectively railed (saturated) for Vᵢₙ˜0 (i.e. current is about constant vs input voltage), and have an abrupt transition for Vᵢₙ˜±0.6V, which is the threshold set by the input DC voltage offset(s) V_{offset1.2}≅ΔV_{d}=R_{drop}*I₁. Note that once the limiter transconductors 331₁, 331₂ engage, the variation of the output current has opposite gradient compared to the main transconductor 320, due to being connected to the output with opposite polarity, and is also much steeper (due to the absence of degeneration resistance 323 R_{E}). As a result, the output current is abruptly clamped.

The threshold voltage at which the limiter transconductors 331₁, 331₂ are turned on, e.g. ΔV_{d} in the embodiment of FIG. 3, is desirably set so that the output voltage swing does not exceed the required limit of the ADC reliability. Advantageously, embodiments of the present disclosure may facilitate an accurate control of the threshold voltage ΔV_{d}. The ΔV_{d} is a function of the emitter followers current (I₁ in FIG. 3). The DC current In may be generated e.g. by a bipolar current source (e.g. 315, FIG. 3) with limited collector-emitter headroom. In high-speed amplifiers, such current sources are typically adjusted for low output capacitance rather than high current precision, which may result in a significant variation of the DC current I₁ across Process/Voltage/Temperature (PVT) variations, and in a low accuracy of the transconductor threshold voltages ΔV_{d}=R_{drop}*I₁ that define the limits on the output voltage of the TIA.

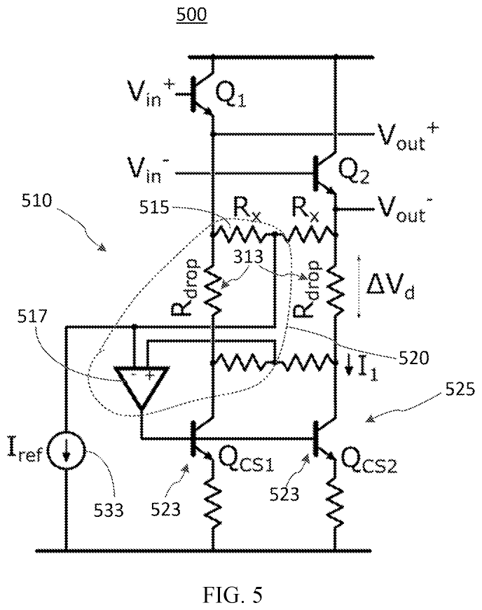

FIG. 5 shows an example embodiment of a threshold control circuit that may be used in the transconductor circuit of FIG. 3 to generate the current(s) I₁. Inputs of the first and second tanh-type current limiters 331₁, 331₂ of the circuit 300 of FIG. 3 connect across the resistor(s) 313 R_{drop}, as illustrated in FIG. 3. A first current source comprising e.g. transistors 523 Q_{CS1}, Q_{CS2} provides a first current I₁ through the resistor(s) 313. The voltage drop ΔV_{d}=I₁*R_{drop} across the resistor(s) 313 defines an input DC voltage offset, and thereby a turn-on voltage, for the first and second tanh-type current limiters 331₁, 331₂, as described above with reference to FIG. 3. A small current I_{ref}<<I₁ from a reference current source 533 is sunk through resistors 515 having a resistance Rₓ>>R_{drop}. The ratio Rₓ/R_{drop} may be greater than 10, or e.g. in the range from about 15 to about 100. A closed-loop scheme using a low-offset operational amplifier 517 sets the base voltage of the first current source(s) and creates a virtual short-circuit between inputs of the operational amplifier 517, thus approximately forcing ΔV_{d}=Rₓ*I_{ref}. The current I_{ref} is isolated from the signal path by the resistors Rₓ 515, therefore can be generated by a MOS current source optimized for high precision rather than low output capacitance.

Embodiments of the circuit of FIG. 3 with the threshold control circuit of FIG. 5 may facilitate an accurate control of a voltage clamping threshold at a TIA output without significantly degrading high-frequency performance of the TIA.

The example embodiments described above are not intended to be limiting, and many variations will become apparent to a skilled reader having the benefit of the present disclosure. For example, although the example embodiments illustrated in FIGS. 3 and 5 have a differential input to differential output configuration, other embodiments may have single input to differential output configuration, single input to single output (SISO) configuration, or a differential input to single output configuration. In case of a single-ended input, the same circuit as in FIG. 3 may be used, but connecting either Vᵢₙ₊ or Vᵢₙ₋ to a fixed DC voltage. Some embodiments may use field-effect transistors instead of, or in combination with, bipolar transistors. In some embodiments, resistor R_{drop} and/or current I₁ in the embodiment of FIG. 3 may be tunable to adjust the limiter threshold. In some embodiments, offsets of the limiter transconductors may be created by introducing a geometry mismatch (e.g. emitter length for a bipolar transistor) between transistors Q₃ and Q₄, and between transistors Q₅ and Q₆. These geometry mismatches may be used instead of, or in combination with, the voltage offset ΔV_{d}.

It will be understood by one skilled in the art that various changes in detail may be affected in the described embodiments without departing from the spirit and scope of the invention as defined by the claims.

1. An apparatus comprising:
a transimpedance amplifier (TIA) with differential outputs; and
a multi-tanh type current limiter connected across the differential outputs of the transimpedance amplifier.

2. The apparatus of claim 1, wherein the multi-tanh type current limiter comprises first and second tanh-type current limiters connected to subtract an output current thereof from an output current of the TIA; and
wherein the first and second tanh-type current limiters are biased to be shifted in voltage.

3. The apparatus of claim 2, wherein the first and second tanh-type current limiters are biased to be shifted by a voltage approximately being a voltage range for linear amplification by the TIA.

4. The apparatus of claim 1 wherein the multi-tanh type current limiter comprises a multi-tanh doublet.

5. The apparatus of claim 1, wherein the multi-tanh type current limiter comprises two non-degenerated transistor pairs.

6. The apparatus of claim 2 wherein the TIA includes a degenerated transistor pair at an output thereof.

7. The apparatus of claim 6 wherein a peak transconductance of each of the first and second tanh-type current limiters is at least double in magnitude a peak transconductance of the degenerated transistor pair.

8. The apparatus of claim 2, wherein the first and second tanh-type current limiters are biased to have threshold voltages of opposite sign, further comprising a threshold control circuit for controlling the threshold voltages.

9. The apparatus of claim 8 wherein the threshold control circuit comprises:
a first resistor R_{drop} for passing a first current I₁ therethrough, a voltage drop ΔV_{d}=I₁*R_{drop} across the first resistor biasing one of the first and second tanh-type current limiters to have a threshold voltage equal to ΔV_{d};
a transistor for tuning the first current I₁;
a voltage feedback circuit comprising a second resistor Rₓ≥10·R_{drop} in parallel with the first resistor; and
a reference current source for flowing a reference current I_{ref} through the second resistor Rₓ;
wherein the voltage feedback circuit further comprises an operational amplifier coupled to the transistor for adjusting the first current I₁ to force the voltage drop across the first resistor R_{drop} to be equal to approximately Rₓ·I_{ref}.

10. The apparatus of claim 8 wherein the threshold control circuit comprises:
a resistor R_{drop} having first and second terminals connected to positive and negative inputs, respectively, of the first and second tanh-type current limiters;
a first current source comprising a transistor and connected to the second terminal of the resistor R_{drop} to flow a first current I₁ therethrough, so that a voltage drop ΔV_{d}=I₁*R_{drop} across the resistor R_{drop} provides one of the threshold voltages for turning on the corresponding one of first and second tanh-type current limiters;
a resistor Rₓ having a first terminal connected to the first terminal of R_{drop}, and a second terminal connected to a second current source for generating a reference current I_{ref}, wherein Rₓ≥10·R_{drop};
an operational amplifier having an output connected to a base or gate of the transistor of the first current source, and inputs connected to the second terminals of the resistors Rₓ and R_{drop}, so as to set ΔV_{d} approximately equal in magnitude to I_{ref}*Rₓ.

11. The apparatus of claim 2, wherein the first and second tanh-type current limiters are biased to have I-V characteristics shifted relative to each other by a voltage offset approximately being a voltage range for linear amplification by the TIA.

12. The apparatus of claim 1 comprising a coherent optical receiver including the TIA.

13. An apparatus, comprising:
a limiting amplifier operable to convert a differential input voltage Vᵢₙ to a differential output current, comprising:
a first circuit having a substantially non-zero first trans-conductance T_{c1} for |Vᵢₙ|≤V₁; and
a limiter circuit having a second trans-conductance T_{c2}, wherein:
T_{c2} is smaller in magnitude than T_{c1} for |Vᵢₙ|≤V₂<V₁, and
T_{c2} is greater in magnitude than T_{c1} in some range of |Vᵢₙ| above V₂;
wherein the limiter circuit is connected so that an output current of the limiter circuit is subtracted from an output current of the first circuit.

14. The apparatus of claim 13 wherein the first circuit comprises an emitter-degenerated or source-degenerated transistor pair.

15. The apparatus of claim 13 wherein the limiter circuit comprises two non-degenerated transistor pairs connected to have two DC voltage offsets of opposite sign.

16. The apparatus of claim 13 wherein the limiter circuit comprises a multi-tanh doublet.

17. The apparatus of claim 16 wherein the multi-tanh doublet comprises two non-degenerated transistor pairs connected to have two DC voltage offsets of opposite sign.

18. The apparatus of claim 13 comprising a coherent optical receiver including the limiting amplifier.
